(19) United States
(12) Patent Application Publication
(10) Pub. No.: US 2008/0278903 A1
(43) Pub. Date: Nov. 13, 2008

(54) Package and Manufacturing Method for Multi-Level Cell Multi-Media Card

(75) Inventors: Jim Chin-Nan Ni, San Jose, CA (US); Abraham Chih-Kang Ma, Fremont, CA (US); Charles Chung Lee, Cupertino, CA (US); Ming-Shiang Shen, Hsin Chuang (TW)

Correspondence Address: LAW OFFICES OF IMAM, 111 N. MARKET STREET, SUITE 1010, SAN JOSE, CA, 95113, US

(73) Assignee: SUPER TALENT ELECTRONICS, INC., San Jose, CA (US)

(21) Appl. No.: 11/929,957

(22) Filed: Oct. 30, 2007

Related U.S. Application Data
(63) Continuation-in-part of application No. 11/864,696, filed on Sep. 28, 2007.
Application No. 11/864,696 is a continuation-in-part of application No. 11/864,671, filed on Sep. 28, 2007.
Application No. 11/864,671 is a continuation-in-part of application No. 10/789,333, filed on Feb. 26, 2004, now Pat. No. 7,318,117.
Application No. 10/789,333 is a continuation-in-part of application No. 11/624,667, filed on Jan. 18, 2007.
Application No. 11/624,667 is a division of application No. 09/478,720, filed on Jan. 6, 2000, now Pat. No. 7,257,714.

(51) Int. Cl. H05K 7/00; H01S 4/00

(52) U.S. Cl. 361/684; 361/737; 29/592.1

(57) ABSTRACT

An embodiment of the present invention includes an electronic data flash memory card (memory card) comprising a top cover (TC), a printed circuit board assembly (PCBA) and a bottom cover (BC). The TC includes a plurality of ultrasonic bonders, a plurality of breakaway tabs (tabs) and a connection device. The PCBA includes at least one memory integrated circuit (IC) and at least one controller IC. The BC includes a plurality of tabs.

The TC and BC are ultrasonically bonded together, at least partially encasing the PCBA.

The controller IC enables the memory card to communicate with an external host device (host) through the connection device to retrieve data files (files) from and transfer files to the host, and to store files on and retrieve files from the memory IC.

The tabs are removable by the user by exerting pressure. Removal of the tabs locks or unlocks the memory card.

### CROSS REFERENCE TO RELATED APPLICATIONS

This application is a continuation in part of U.S. patent application entitled “Backward compatible extended-MLC USB plug and receptacle with dual personality”, U.S. application Ser. No. 11/864,696, filed on Sep. 28, 2007, the disclosure of which is incorporated herein by reference as though set forth in full.

This application is also a continuation in part of U.S. patent application entitled “Electronic data flash card with various flash memory cells”, U.S. application Ser. No. 11/864,671, filed Sep. 28, 2007, the disclosure of which is incorporated herein by reference, as though set forth in full.

This application is also a continuation in part of U.S. patent application entitled “System and method for controlling flash memory”, U.S. application Ser. No. 10/789,333, filed on Feb. 26, 2004, the disclosure of which is incorporated herein by reference as though set forth in full.

This application is a continuation in part of U.S. patent application entitled “Electronic data storage medium with fingerprint verification capability”, U.S. application Ser. No. 11/624,667, filed on Jan. 18, 2007, the disclosure of which is incorporated herein by reference, as though set forth in full, and which is a division of application U.S. application Ser. No. 09/478,720, filed Jan. 6, 2000, entitled “Electronic Data Storage Medium with Fingerprint Verification Capability”.

### BACKGROUND OF THE INVENTION

1. Field of the Invention

The present invention relates generally to the field of portable flash cards, and particularly to portable flash card with optional write protection mechanism(s).

2. Description of the Prior Art

Flash memory cards, including Multi-Media Card (MMC) and other formats, have been widely deployed as a method for storing and transporting data files including images, video, and sound, between peripherals such as digital cameras and music players and personal computers (PCs) and other devices.

Flash memory cards typically include memory and controller circuitry to enable storing, addressing, and retrieval of data files. Many memory cards use Multi-Level Cell (MLC) memory Integrated Circuit (IC), as well as a controller IC.

Users often store sensitive data files on their flash memory cards. Occasionally, users inadvertently erase or modify sensitive files stored on their flash memory cards.

Furthermore, numerous formats of flash memory cards exist. Some of the formats use the same size and form, while other formats are smaller or larger. Independent manufacturers of flash memory cards may desire to offer a product line to include all the various formats. It is desirable to introduce modularity and interchangeability in the manufacturing process to reduce cost.

What is desired is an improved package and manufacturing method for multi-MLC memory flash card.

### SUMMARY OF THE INVENTION

Briefly, an embodiment of the present invention includes an electronic data flash memory card comprising a top cover, a printed circuit board assembly (PCBA) and a bottom cover. The top cover includes a plurality of ultrasonic bonders, a plurality of breakaway tabs, and a connection device. The PCBA includes at least one memory integrated circuit (IC) and at least one controller IC. The bottom cover includes a plurality of breakaway tabs. The breakaway tabs are removable by the user by exertion of pressure thereon. The removal of the breakaway tabs by the user locks or unlocks the electronic data flash memory card.

In accordance with an embodiment of the present invention, the top cover and bottom cover are ultrasonically bonded together to at least partially encase the PCBA.

The controller IC enables the electronic data flash memory card to communicate with an external host device through the connection device for the purpose of retrieving data files from the external host device and storing the data files on the memory IC and retrieving data files from the memory IC and transferring the data files to the external host device.

The foregoing and other objects, features and advantages of the present invention will be apparent from the following detailed description of the embodiments of the present invention which make reference to several figures of the drawing.

### IN THE DRAWINGS

FIG. 1 shows a block diagram of an electronic data flash memory card 10 according to an embodiment of the present invention.

FIG. 2 shows an angular top view 31, an angular bottom view 32, and an exploded view 33 of an electronic data flash memory card 30 according to one embodiment of the present invention.

FIG. 3(a) shows a memory card 30 as it is inserted into a host device 3, according to an embodiment of the present invention.

FIG. 3(b) shows a block diagram of a host device 130 interfacing with a memory card 30, according to an embodiment of the present invention.

FIG. 4 shows four top views of the memory card 30 with various combinations of the four breakaway tabs 38 removed or intact, according to an embodiment of the present invention.

FIG. 5 shows an angular top view 125, bottom angular view 126, and exploded view 127 of an electronic data flash memory card 120 in accordance with a different embodiment of the present invention.

FIG. 6 shows a top angular view of an electronic data flash memory card 141 according to another embodiment of the present invention.

FIG. 7 shows a top angular view of a top cover 750, which is a component of an electronic data flash memory card according to an embodiment of the present invention.

FIG. 7(a) an exploded view of an electronic data flash memory card 700 according to an embodiment of the present invention.

FIG. 7(b) shows an angular front top view 701 and an angular bottom rear view 702 of the electronic data flash memory card 700 according to an embodiment of the present invention.

FIG. 8 shows a top angular view of an top cover 850, which is a component of an electronic data flash memory card according to an embodiment of the present invention.

FIG. 8(a) an exploded view 801, an angular front top view 802 and an angular rear bottom view 803 of an electronic data flash memory card 800 according to an embodiment of the present invention.

### DETAILED DESCRIPTION OF THE PREFERRED EMBODIMENT OF THE PRESENT INVENTIONS

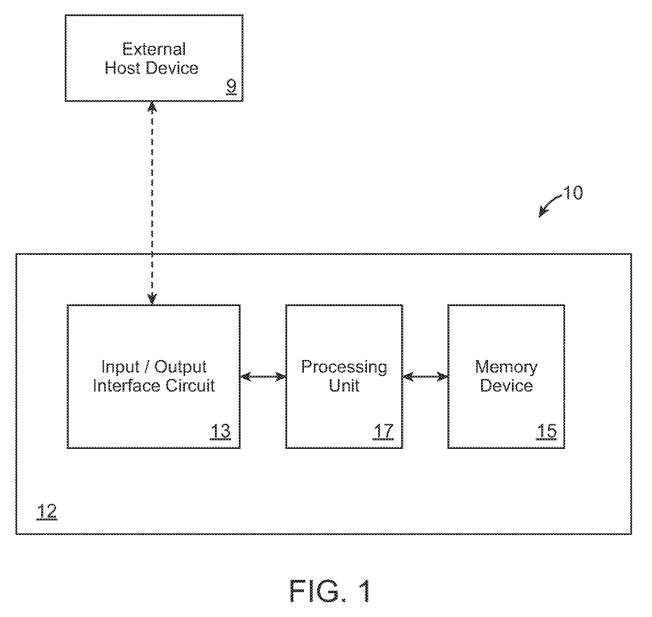

Referring now to FIG. 1, a block diagram of an electronic data flash memory card 10 is shown according to an embodiment of the present invention. The memory card 10 is shown to include a processing unit 17, an input/output (I/O) interface circuit 13, and a memory device 15. The interface circuit 13 is coupled to the processing unit 17 to allow for the electronic data flash memory card 10 to communicate with the processing unit 17. The processing unit 17 generally directs information flow between the memory device 15 and interface circuit 13 and may perform functions such as error correction coding. In an embodiment of the present invention, the processing unit 17 is coupled to a plurality of LEDs (not shown) for status indication such as sufficient power indication, read/write flash activity, or any other suitable indications. Processing unit 17 is shown coupled to one or more flash memory devices 15.

The memory card 10 is adapted to be accessed by a host device 9 via an interface mechanism, such as electrical, optical, infra-red, or wireless connector (not shown). The memory device 15 is mounted on the card body 12. In one embodiment of the present invention, the memory device 15 is comprised of Multi-Level Cell (MLC) memory circuitry. The memory device 15 stores in a known manner therein one or more data files from the host device 9. The data file can include digitally stored images, video, music, text, or other file formats.

The interface circuit 13 is mounted on the card body 12, and can be activated so as to establish communication with the host device 9 as mentioned above. In one embodiment, the interface circuit 13 includes circuits and control logic associated with the Multi-Media Card (MMC) interface standard and structure that is connectable to an associated socket connected or mounted on the host device 9.

MMC is a widely used flash card standard for connecting flash devices connectable to host devices such as a personal computer (PC), digital camera, mobile phones, and other host devices. In other embodiments, the interface circuit 13 can interface with the host device 9 using other standards such as reduced size (RS) MMC, MMC plus, MMC mobile, MMC-mini, MMC-micro, secure digital (SD), secure digital input output (SDIO) and others.

The processing unit 17 is mounted on the card body 12, and is connected to the memory device 15 and the interface circuit 13, for example by way of associated conductive traces or wires disposed on card body 12 or other connection methods known and used in the industry. The processing unit 17 may be controlled by a program stored at least partially in the memory device 15 such that the processing unit 17 is operable selectively in: (1) a programming mode or storing mode, where the processing unit 17 activates the interface circuit 13 to receive the data file from the host device 9, and to store the data file in flash memory device 15; and (2) a data retrieving mode, where the processing unit 17 activates the interface circuit 13 to transmit the data file(S) stored in the flash memory device 15 to the host device 9; and (3) a data resetting mode, where the data file is erased from the memory device 15. Where the user desires to modify a data file already existing in the memory card 10, various methods exist to carry out the user's instruction. For example, in one embodiment of the present invention, the memory card 10 first goes into mode 3, erasing the existing data file, then goes to mode 1, and writes the new data file.

The host device 9 may include a display unit (not shown), which is connected to the processing unit 17 when the memory card 10 is in operation via an interface bus or a card reader (not shown). The display unit may be used for showing the data file exchanged with the host device 9, for showing the operating status of the memory card 10, for showing the amount of free memory available on the memory device 15, or other information or messages.

It should be noted that the architecture shown in FIG. 1 is exemplary, and other architectures are contemplated. For example, rather than having one connection between the interface circuit 13 and the processing unit 17, and another connection between the processing unit 17 and the memory device 15, one single bus may be used, with the interface circuit 13, the processing unit 17, and the memory device 15 each being independently connected to said bus (not shown).

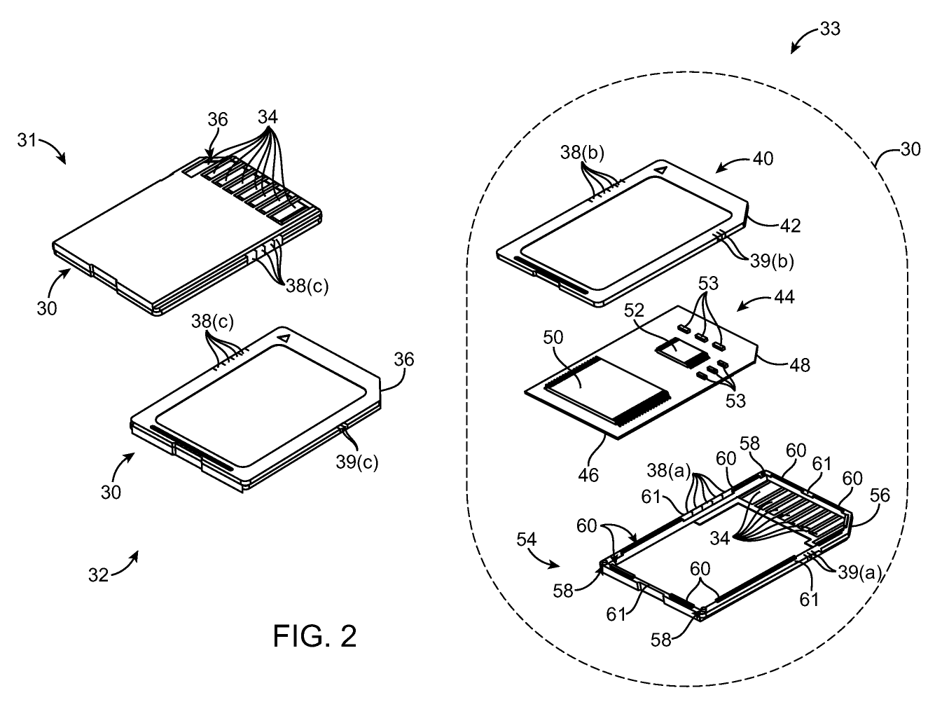

Referring now to FIG. 2, an angular top view 31, an angular bottom view 32, and an exploded view 33 of an electronic data flash memory card 30 is shown according to one embodiment of the present invention. The top view 31 and bottom view 32 show the memory card 30 to be generally rectangular in shape, and to include a corner notch 36, a plurality of contact fingers (or connection device) 34, a plurality of memory card breakaway tabs 38(c), and a plurality of memory card breakaway notches 39(c). The corner notch 36 is shown to be shaped as a triangular cut-out, located on one corner of the memory card 30. The memory card breakaway tabs 38(c) are shown to be generally square-shaped tabs situated generally on one lengthwise edge of the memory card 30. The memory card breakaway notches 39(c) are shown to be generally square-shaped tabs situated generally on the lengthwise edge of the memory card 30, opposite from the lengthwise edge on which the memory card breakaway tabs 38(c) are situated. The contact fingers 34 are shown to be squares, comprised of conductive material, and located substantially along one widthwise edge of the memory card 30, adjacent to the corner notch 36.

It should be noted that the shape and dimensions of the memory card 30, the corner notch 36, the memory card breakaway tabs 38(c), the memory card breakaway notches 39(c) and the contact fingers 34 shown here are exemplary, and other shapes and dimensions are anticipated. Furthermore, the number of the memory card breakaway tabs(c) 38, memory card breakaway notches 39(c), and contact fingers 34 are exemplary, and other numbers are anticipated. In one embodiment of the present invention, the number, shape, and position of the contact fingers 34 conform to the MMC standard commonly used in the industry. It is contemplated that in other embodiments of the present invention, the number, shape, and position of the contact fingers 34 may conform to other standards.

The breakaway notches 39(c) are formed in such a manner to allow a user to break them off by exerting pressure. Certain host devices (not shown) may have a protrusion situated in a manner such that the memory card 30 cannot easily be inserted into the host device unless one or more of the breakaway notches 39(c) are removed. Removing the breakaway notches 39(c) by the user allows the memory card 30 to be easily inserted into such host devices, and once inserted, to be firmly held in place. With the host device protrusion (not shown) fitting into the cavity formed by removing the breakaway notches 39(c), the memory card 30 is firmly held in place and is less likely to be shaken loose. This also advantageously improves the contact between the memory card 30 and the host device.

The contact fingers 34 are formed from conducting metals such as copper. It should be noted that copper is only exemplary, and other metallic elements or alloys are contemplated. In one embodiment of the present invention, the contact fingers (or connection device) 34 serves to allow electrical conductivity between the memory card 30 and the host device (not shown).

The function of the breakaway tabs 38(c) will be discussed hereinbelow.

The exploded view 33 shows the memory card 30 to include a bottom cover 40, a printed circuit board assembly 44, and a top cover 54. The bottom cover 40 is shown to be generally rectangular in shape, with a plurality of bottom cover breakaway tabs 38(b) situated generally along one lengthwise edge thereof, a plurality of bottom cover breakaway notches 39(b) situated generally along one lengthwise edge and opposite to the edge on which the bottom cover breakaway tabs 38(b) are situated, and a corner notch 42, shaped as a triangular corner cut-out, situated on one corner thereof. The printed circuit board assembly (PCBA) 44 is shown to be generally rectangular in shape, and comprise a printed circuit board (PCB) 46, a memory integrated circuit (IC) 50, a controller IC 52, and a plurality of electronic components 53 situated thereon.

The PCB 46 is shown to be generally rectangular in shape, having a corner notch 48, shaped as a triangular cut-out, and located on one corner thereof.

The memory IC 50 stores digitized files, such as images, video, audio, or text files. In one embodiment, the memory IC 50 substantially contains the circuitry described in the memory device 15 above, and shown in the block diagram of FIG. 1. The controller IC 52 controls interfacing with host devices, including access to and from the memory IC 50. In one embodiment, the controller IC 52 generally directs information flow between the interface circuit 13 and the memory device 15. The electronic components 53 may include capacitors, resistors, or other components necessary to enable transfer of data and control signals between the memory IC 50, the controller IC 52, and the host device (not shown). The functionalities of the memory IC 50 and the controller IC 52 are discussed more fully above. A detailed discussion of the foregoing is avoided due to redundancy.

The top cover 54 is shown to be generally rectangular in shape, with raised edges 61 and a corner notch 56, shaped as a triangular cutout and disposed on one of it is corners. The top cover is shown to further include a plurality of contact fingers 34 situated substantially along one widthwise edge, adjacent to the corner notch 56 and inside the raised edge 61 thereof. Situated substantially along the raised edges 61 are shown a plurality of ultrasonic bonders 60. The ultrasonic bonders 60 are shown to be raised protrusions extending a portion of the raised edges 61. In the embodiment of the present invention shown in FIG. 2, the raised edges 61 are wider than the ultrasonic bonders 60.

Situated on the raised edges 61 of the three corners of the top cover 54 that are not the corners including the corner notch 56, are shown three positioning posts 58.

The top cover is further shown to include a plurality of top cover breakaway tabs 38(a) shaped generally as square tabs and situated along one lengthwise edge thereof, and a plurality of top cover breakaway notches 39(a), shaped generally as square tabs, and situated along the lengthwise edge opposite to the edge on which the top cover breakaway tabs 38(a) are situated.

It should be noted that where numbers are given, they are only exemplary, and other numbers are anticipated.

In one embodiment, when the memory card 30 is physically inserted into a host device slot (not shown), the corner notch 36 of the memory card 30 matches a triangular corner protrusion in the host device slot, to ensure that the memory card 30 is inserted correctly. If the memory card 30 is inserted incorrectly into the host device slot, the triangular corner protrusion of the host device slot will touch a corner of the memory card 30, and obstruct it from being fully inserted into the host device slot.

During the manufacturing process, the PCBA 44 is placed inside the top cover 54, with the raised edges 61 of the top cover 54 surrounding the PCB 46, and the corner notch 48 of the PCB 46 inside the corner notch 56 of the top cover 54. Thereafter, the bottom cover 40 is attached to the top cover 54, with the positioning posts 58 of the top cover 54 inserted into matching grooves (not shown) in the bottom cover 40. The insertion of the positioning posts 58 of the top cover 54 into matching grooves in the bottom cover 40 ensures that the top cover 54 and the bottom cover 40 are positioned to align relative to each other. Thereafter, the top cover 54 and bottom cover 40 are joined with ultrasonic bonding, using the ultrasonic bonders 60.

The methods and processes for ultrasonic bonding are well-known to those familiar with the art, and a detailed discussion thereof is avoided.

The top cover breakaway tabs 38(a) are aligned with the bottom cover breakaway tabs 38(b). Once the top cover 54 is bonded to the bottom cover 40, the top cover breakaway tabs 38(a) and the bottom cover breakaway tabs 38(b) together form the memory card breakaway tabs 38(c).

The top cover breakaway notches 39(a) are aligned with the bottom cover breakaway notches 39(b). Once the top cover 54 is bonded to the bottom cover 40, the top cover breakaway notches 39(a) and the bottom cover breakaway notches 39(b) together form the memory card breakaway notches 39(c).

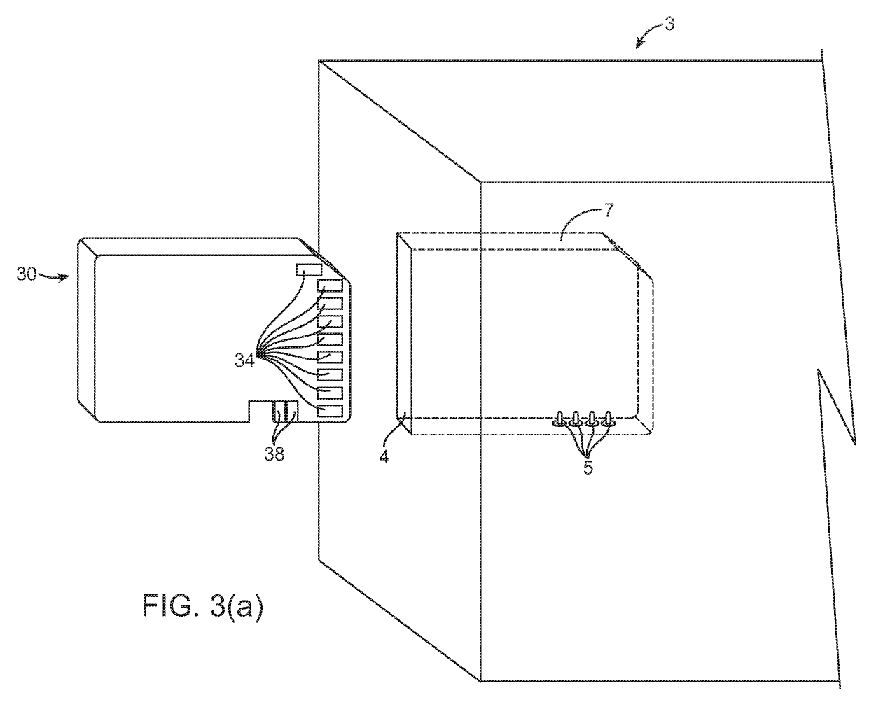

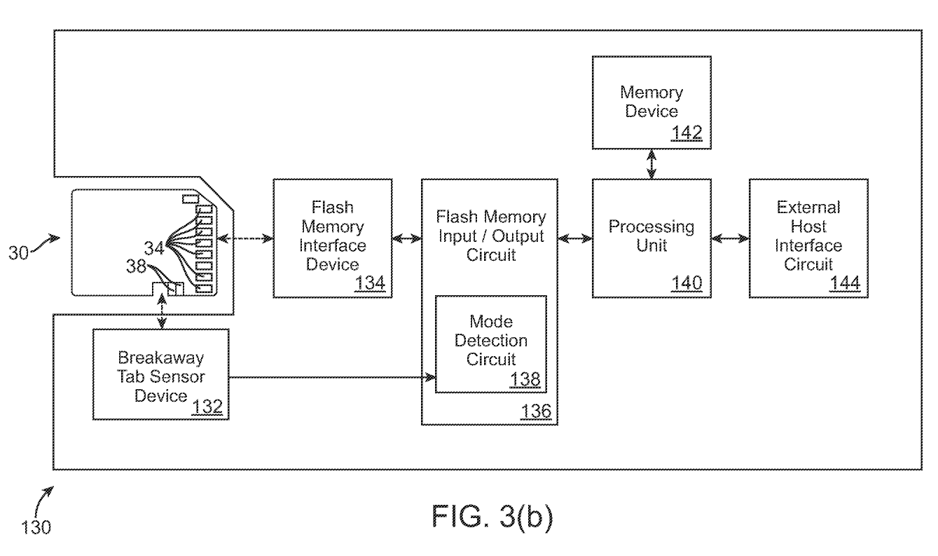

Referring now to FIG. 3(a), a memory card 30 is shown as it is inserted into a host device 3, according to an embodiment of the present invention. The host device 3 may be a music player, voice recorder, mobile phone, PC, digital camera or any other device that can benefit from external, removable, and portable flash memory storage. It should be noted that also contemplated are any other host device where the user wishes to have the ability to protect data files from modification or erasure. The host device 3 is shown to include, situated on one side, a generally rectangular shaped memory card cavity opening 4. The cavity opening 4 is shown leading to a memory card cavity 7 inside the host device. The card cavity 7 is shown to be shaped generally rectangular, and substantially the same size and shape as the memory card 30. Shown situated inside the card cavity are a plurality of breakaway tab sensors 5. The tab sensors 5 detect the presence or absence of the breakaway tabs 38, using either mechanical pressure, infra-red, laser, optical, or other means. The tab sensors 5 are situated such that when the memory card 30 is fully inserted into the card cavity 7, the tab sensors 5 are aligned with the position of the breakaway tabs 38 on the memory card. If any of the breakaway tabs 38 are broken off, the tab sensors 5 detect the breakaway tabs 38 that have been broken off.

It should be noted that although FIG. 3(a) shows a memory card 30 with room for four breakaway tabs 38, two of which are shown broken off, the numbers are only exemplary, and different numbers of breakaway tabs 38 and tab sensors 5 are contemplated. Furthermore, it should be noted that the shape, number, and position of the contact fingers 34 shown is exemplary, and different numbers, shapes, and positions of contact fingers 34 are anticipated.

Users can break off the breakaway tabs 38 individually from the memory card 30 by simply exerting pressure at the edge of the breakaway tabs 38. As discussed hereinbelow, where a breakaway tab 38 has been broken off, it may also be referred to as “removed.” Where a breakaway tab 38 has not been removed, it may also be referred to as “intact.” As will be discussed further below, in an embodiment of the present invention, the user of the memory card 30, by breaking off the breakaway tabs 38, can limit storing and modifying data on the memory card 30.

As discussed, in operation, the memory card 30 can be in one of three modes: (1) a programming or storing mode; (2) a data retrieving mode; and (3) a data resetting mode. In the first (programming or storing) and third (data resetting) modes, the data stored on the memory card 30 is modified, incremented, or erased. In the second (data retrieving) mode, the data in the memory card 30 is neither modified, incremented, nor erased.

Based upon the number and combination of breakaway tabs 38 that have been removed, the host device will, or will not, go into some of the modes described above. For example, if, the host device does not go into modes 1 and 3, the data files in the memory card 30 cannot be modified, incremented, or erased, and the memory card 30 is deemed to be “locked.” Conversely, if the host device can go into modes 1 and 3, the data files can be modified, incremented, or erased, and the memory card is deemed to be “unlocked.”

Referring now to FIG. 3(b), a block diagram of a host device 130 is shown interfacing with a memory card 30, according to an embodiment of the present invention. The memory card 30 is shown to include a plurality of contact fingers 34 and breakaway tabs 38. It should be noted that the number of contact fingers 34 and breakaway tabs 38 shown in FIG. 3(b) are only exemplary, and in different embodiments of the present invention, different numbers of contact fingers 34 and breakaway tabs 38 are contemplated.

The host device 13 may be a music player, voice recorder, mobile phone, PC, or digital camera. It should be noted that also contemplated are any other host device where the user wishes to have the ability to protect data files from modification or erasure. The host device 130 is shown to include a breakaway tab sensor 132, a flash memory interface device 130, a flash memory input/output (I/O) circuit 136. The I/O circuit 136 is itself shown to include a mode detection circuit 138. The host device 130 is shown to further include a processing unit 140, a memory device 142, and an external host interface circuit 144.

The breakaway tab sensor device 132 is shown to be connected to the mode detection circuit 138, which itself is shown to be a part of the flash memory I/O circuit 136. The flash memory interface device 134 is also shown to be connected to the flash memory I/O circuit 136. The flash memory I/O circuit 136 is shown to be connected to the processing unit 140. The processing unit 140 is shown to be connected to the memory device 142, and the external host interface circuit 144. As used herein, “connected” may include electrical, optical, infra-red, wireless, or other methods of connection known to those well-versed in the art. Furthermore, it is contemplated that within one host device 130, “connection” may vary. For example, the flash memory interface device 134 may be connected to the flash memory I/O circuit 136 using electrical copper connections, whereas, for example, within the same host device 130, the connection between the processing unit 140 and the external host interface circuit 144 may be via wireless or infra-red connection.

The breakaway tab sensor 132 is operable to detect the number of breakaway tabs 38 that have been removed from the memory card 30. The flash memory interface device 134 interfaces with the memory card 30 via electrical, infra-red, wireless, or other methods. The flash memory I/O circuit 136 contains therein circuitry and logic to control transfer of data files to the flash memory interface device 134. The mode detection circuit 138 is the portion of the I/O circuit 136 that determines the mode in which the host device 130 is communicating with the memory card 30. The processing unit 140 contains therein circuitry and logic that control operations of the host device 130. The memory device 142 may include a hard drive, flash memory, MLC, or other memory devices, or a combination thereof. It is contemplated that the memory device 142 may include a hierarchy of memory devices, with smaller, faster memory devices acting as cache, and larger, slower memory devices acting as main memory. The external host interface circuit 144 contains circuitry and logic to connect the processing unit to various internal and external devices such as function keys, mouse, keyboard, display units, joystick, image capturing devices, voice capturing devices, wireless signal capturing devices or other devices (not shown). Furthermore, it is contemplated that the external host interface circuit 144 may interface with one or a plurality of devices (not shown).

In operation, the breakaway tab sensor device 132 identifies the breakaway tabs 38 that have been removed from the memory card 30 and communicates this information to the mode detection circuit 138. The mode detection circuit 138 uses the information received from the breakaway tab sensor device 132 to determine the mode(s) in which the memory card 30 is allowed to communicate with the external host device 130.

The user of the external host device 130, using user interface mechanisms such as a keyboard, mouse, function key set, joystick, etc, (not shown) instructs the host device 130 the desired data file transfer transaction (“transaction”) between the host device 130 and the memory card 30. The interface mechanisms interfaces with the external host interface circuit 144, which communicates this information to the processing unit 140. The processing unit 140 communicates this information to the I/O circuit 136. The I/O circuit 136 determines whether the desired transaction is compatible with the allowable modes, as determined by the mode detection circuit 138.

For example, if the transaction desired by the user is the writing of data files onto the memory card 30, and if the mode detection circuit determines that the memory card 30 and the host device 130 can only communicate in mode 2, then the desired transaction is not allowed. The I/O circuit 136 communicates this information back to the processing unit 140, which may communicate it back to the external host interface circuit 144. The external host interface circuit 144 may communicate this information back to the user, for example through a display screen (not shown), or by flashing one or more light emitting diodes (LEDs) (not shown) or by generating a beeping sound on a speaker (not shown).

On the other hand, if the memory card 30 and the host device 130 can communicate in all modes, then the desired transaction is allowed. In that case, the processing unit 140 retrieves the data files, transfers them to the I/O circuit 136, which in turn transfers them to the flash memory interface device 134, which transfers the data files to the memory card 30 for storage.

It should be noted that the architecture of the external host device 130 shown in FIG. 3(a) is exemplary, and other architectures and additional functionalities are contemplated. For example, the mode detection circuit 138 can be a part of the processing unit 140, rather than the I/O circuit 136. Alternatively, the memory device 142 and the I/O circuit 136 may be directly connected, such that once a transaction is commenced, the I/O circuit 136 controls the data transfer, thus releasing the processing unit 140 to handle other instructions.

As discussed above, in this embodiment of the present invention, the user determines whether the memory card 30 is “locked” or “unlocked” by breaking off the breakaway tabs 38. An exemplary scheme for locking and unlocking the memory card 30 is discussed further below.

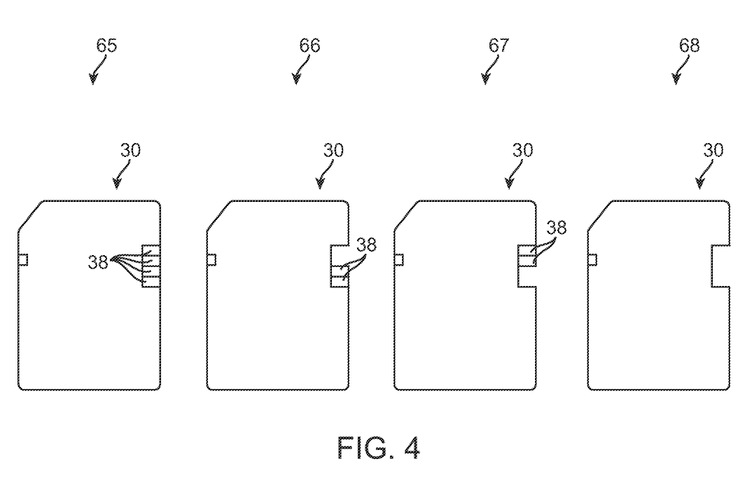

Referring now to FIG. 4, four top views of the memory card 30 is shown with various combinations of the four breakaway tabs 38 removed or intact, according to an embodiment of the present invention.

In view 65, all four breakaway tabs are shown to be intact. In view 66, the bottom two breakaway tabs 38 are shown to be intact, and the top two breakaway tabs 38 are shown to be removed. In view 67, the top two breakaway tabs 38 are shown to be intact, and the bottom two breakaway tabs 38 are shown to be removed. In view 68, all four breakaway tabs 38 are shown removed.

Table 1 shows an exemplary data protection scheme for the memory card 30, as shown in FIG. 4.

TABLE 1

| View | Top Breakaway tabs | Bottom Breakaway tabs | Data Protection |
|---|---|---|---|
| 65 | Intact | Intact | Un-locked |
| 66 | Broken | Intact | Locked |
| 67 | Intact | Broken | Un-locked |
| 68 | Broken | Broken | Locked |

It should be noted that the scheme shown in Table 1 is only exemplary, and other schemes are contemplated. For example, a different number of breakaway tabs 38 can be used, or the removal of all breakaway tabs can indicate write-lock protection, etc.

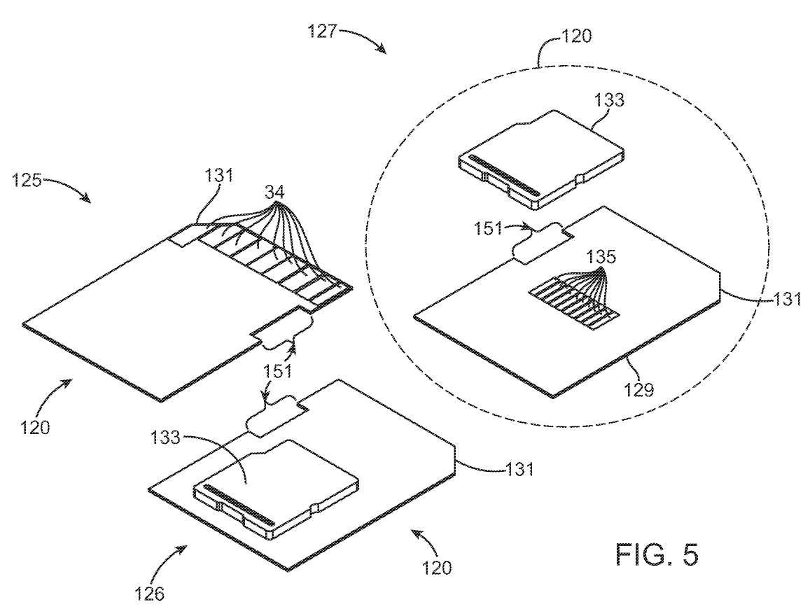

Referring now to FIG. 5, an angular top view 125, bottom angular view 126, and exploded view 127 of an electronic data flash memory card 120 is shown in accordance with a different embodiment of the present invention.

In the exploded view 127, the memory card 120 is shown to include a small format memory card 133 and a PCB 129. The PCB 129 is shown to be generally rectangular in shape, having a corner notch 131, shaped generally as a triangular cut-out situated on one corner thereof, and a breakaway tab recess 151 situated substantially along the lengthwise edge thereof. The PCB 129 is shown to further include a plurality of metal pads 135.

In the top view 126, the memory card 120 is shown assembled, with the small format memory card 133 situated generally in the middle thereof. In the top view 125, the memory card 120 is shown to include a plurality of contact fingers 34 situated substantially along the widthwise edge thereof. In one embodiment of the present invention, the contact fingers 34 are situated on the PCB 129 on the opposite side where the small format memory card 133 is located.

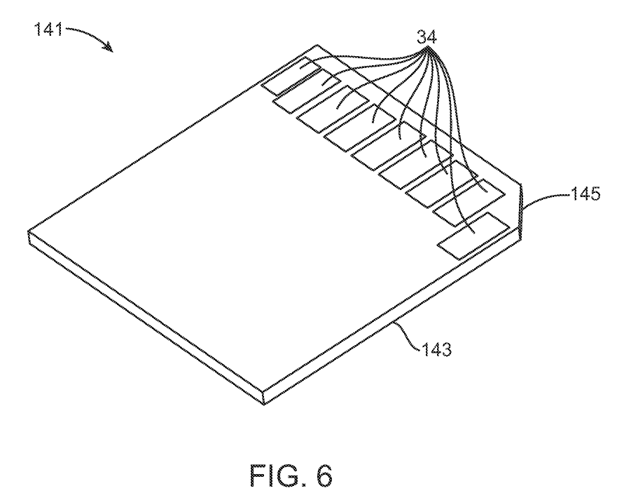

In one embodiment of the present invention, the PCB 129 is shaped substantially to conform with the dimensions of the MMC standard, and the number, position, and the shape of the contact fingers 34 are likewise in conformance with the MMC standards. It should be noted, however, that other standards, such as SD, are also contemplated. In one embodiment of the present invention, the small format memory card 133 is a mini-MMC. However, other memory cards, such as micro-MMC are also contemplated. Furthermore, although only one small format memory card 133 is shown in FIG. 6, it is anticipated that more than one small format memory card 133 may be used.

In one embodiment of the present invention, the breakaway tab recess 151 renders the memory card 120 permanently unlocked. It is contemplated that in other embodiments of the present invention, the breakaway tab recess 151 is replaced by one or a plurality of breakaway tabs (not shown) which a user can break off by applying pressure, thus allowing the user to remove said tabs to render the memory card 120 locked or unlocked, as discussed above.

In manufacture, the PCB 120 is fabricated using commonly known PCB manufacturing processes. Thereafter, the small format memory card 133 is mounted on the PCB 120 using commonly known surface mount technology (SMT). During the mount process, the pins or contact fingers (not shown) of the small format memory card are attached to the metal pads 135 of the PCB 129.

In one embodiment of the present invention, the number and function of the contact fingers 34 have a one-to-one correlation with the number and function of the pins or contact fingers on the small format memory card 133, in which case the PCB 129 merely connects the pins from the small format memory card 133 to the correlating contact finger 34 on the PCB 129. In other embodiments of the present invention, the number and function of the contact fingers 34 do not have a one-to-one correlation with the number and function of the pins on the small format memory card 133, in which case the PCB 129 may contain additional circuitry, for example in the form of an extra IC (not shown) surface mounted on the PCB 129 in order to make the pins from the small format memory card 133 compatible with the contact fingers 34.

The manner of converting the pins from small format memory cards 133 such as Micro-MMC and Mini-MMC into pins for a different format memory card are well-known to those in the art, are not discussed herein.

Referring now to FIG. 6, a top angular view of an electronic data flash memory card 141 is shown according to another embodiment of the present invention. The memory card 141 is shown to be generally rectangular in shape, having a corner notch 145, shaped generally as a triangular cut-out, situated on one corner thereof. The memory card 141 is shown to include a plurality of contact fingers 34 substantially along one widthwise edge thereof.

In one embodiment of the present invention, the memory card 141's shape, dimensions, as well as the position, number, and shape of the contact fingers 34 situated thereon conform to MMC standards, and the memory card 141 communicates with a host device (not shown) using the MMC standard commonly used in the industry. In another embodiment of the present invention, the memory card 141's shape, dimensions, as well as the position, number, and shape of the contact fingers 34 situated thereon conform to SD standards, and the memory card 141 communicates with a host device (not shown) using the SD standard commonly used in the industry. In other embodiments of the present invention, the shape and size of the memory card 141, as well as the position, number, and shape of the contact fingers 34 conform to other standards, and the memory card 141 communicates with the host device (not shown) according to such other standards.

In the embodiment of the present invention shown in FIG. 6, the memory card 141 is a chip on board (COB). COB manufacturing methods are well-known in the industry, but, by way of example, generally include manufacturing of a chip or IC, surface mounting the IC on a PCB, and thereafter, placing the PCB in a mold and pouring plastic, resin, or epoxy on the PCB, yielding a single, encapsulated device containing a chip and the contact fingers.

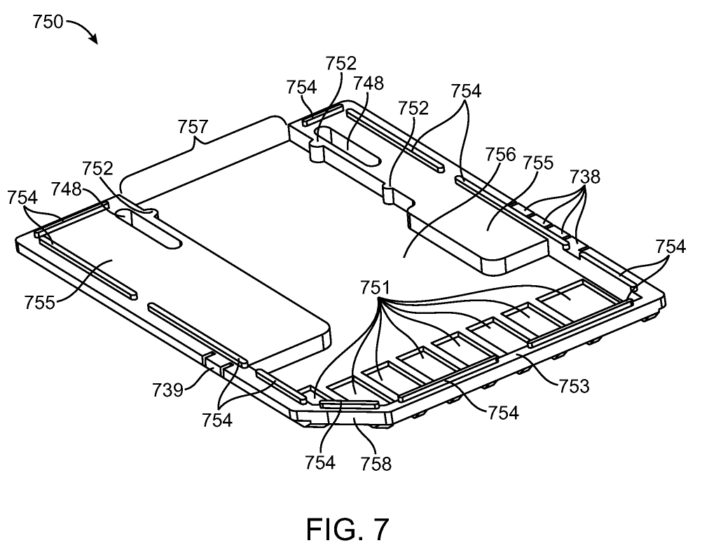

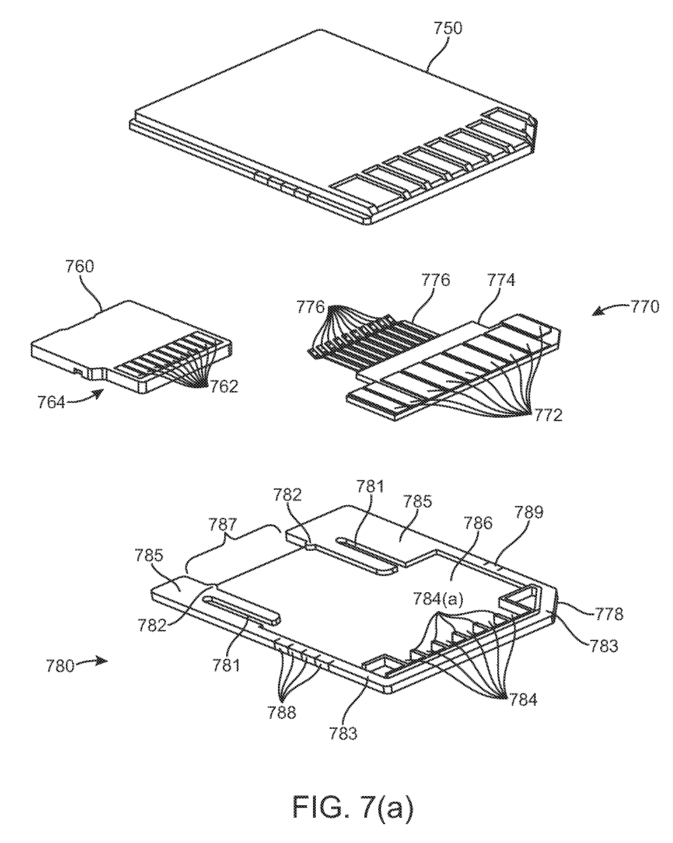

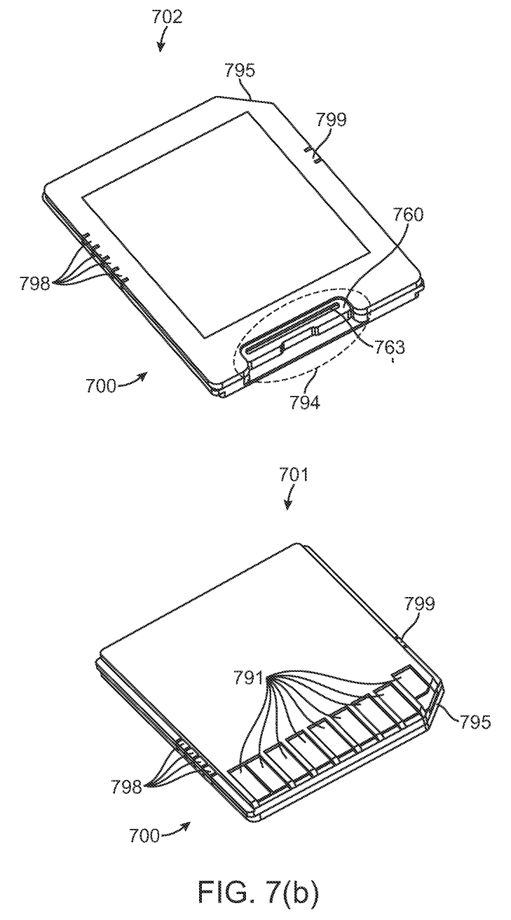

Referring now to FIG. 7, a top angular view of a top cover 750, is shown according to another embodiment of the present invention. The top cover 750 is a part of a electronic data flash memory card 700 (not shown in FIG. 7).

The top cover 750 is shown to be generally square in shape, with two raised platforms 755 situated generally on one surface thereof, a central cavity 756 generally in the middle thereof, and a corner notch 758, shown to be generally shaped as a triangular cutout, on one corner thereof. In one embodiment of the present invention, the corner notch 758 is shaped generally to conform to the SD or MMC size standards, but it is anticipated that in other embodiments, the corner notch 758 may be shaped to conform to standards of other memory cards. Shown situated inside the raised platforms 755 are two compression channels 748, shaped generally as linear cutouts in the raised platforms 755.

The top cover 750 is shown to further include raised edges 753 extending along the edge adjacent to the corner notch 758, and extending around to merge with the raised platforms 755. The top cover 750 is shown to further include a plurality of ultrasonic bonders 754, shown to be formed as raised protrusions, narrower in width than the raised edges 753, along three edges, and a portion of a fourth edge. Along the inner edges of the raised platform 755 and facing the central cavity 756 are shown formed a plurality of protrusion posts 752, which are shown to be formed generally as solid, semi-cylindrical protrusions.

The top cover 750 is shown to further include an opening 757 disposed substantially in the middle of the edge opposite to the edge on which the corner notch 758 is situated and between the two edges adjacent to the raised platforms 755. The length of the opening 757 is substantially equal to the width of a smaller format memory card 760, as will be discussed further hereinbelow.

The top cover 750 is shown to further include a plurality of connector openings 751, shown to be formed generally as rectangular cutouts, along the edge opposite to the edge on which the opening 757 is situated. In an embodiment of the present invention, the shape, number, and position of the connector openings 751 conform to the shape, number, and position of connectors in the SD or MMC standards, but in other embodiments, it is anticipated that the shape, number, and position of the connector openings 751 conform to other standards used and adopted by the industry.

The top cover 750 is shown to further include a breakaway notch 739 along an edge thereof adjacent to the corner notch 758. The top cover 750 is shown to further include and a plurality of breakaway tabs 738 along the edge opposite to the edge on which the breakaway notch 739 is situated. It should be noted that the number of breakaway tabs 738 and breakaway notch 739 shown is exemplary, and it is anticipated that in other embodiments, different numbers of breakaway tabs 738 or breakaway notches 739 may be used. The shape and function of the breakaway tabs 738 and the breakaway notch 739 are similar to the breakaway tabs 38 and breakaway notches 39, discussed hereinabove, and further discussion thereof is avoided to eliminate redundancy.

Referring now to FIG. 7(a) an exploded view of an electronic data flash memory card 700 is shown according to another embodiment of the present invention.

The electronic data flash memory card 700 is shown to include the top cover 750, a smaller format memory card 760, a terminal module 770, and a bottom cover 780. The structure and components of the top cover 750 are discussed hereinabove, and additional discussion thereof is avoided in order to eliminate redundancy.

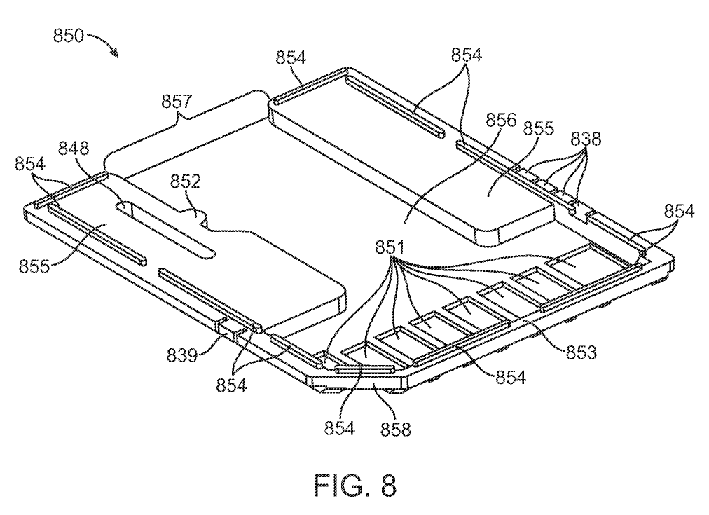

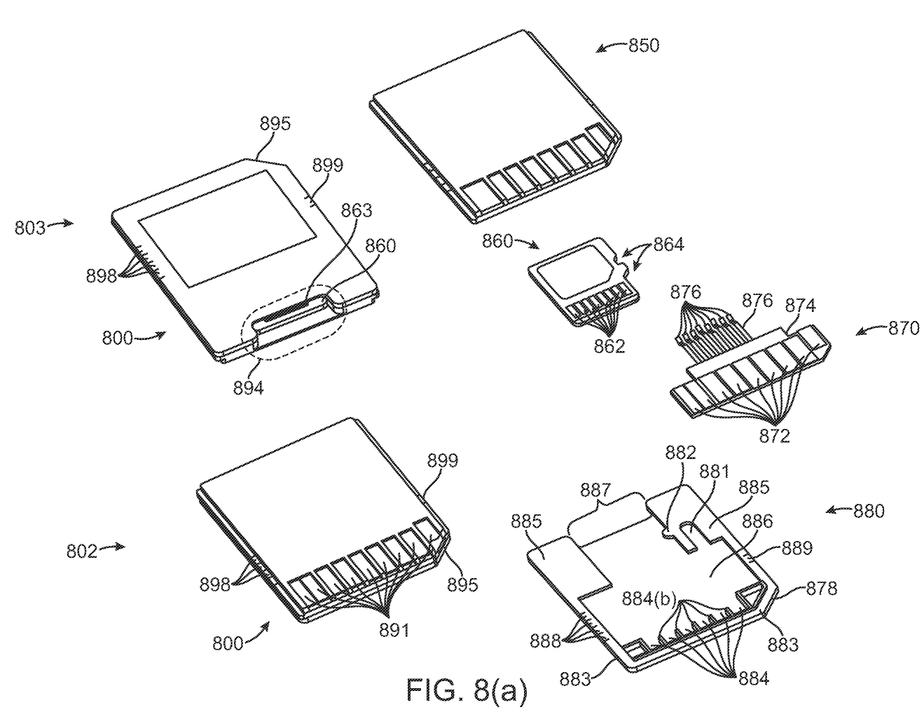

The terminal module 770 is shown to include a plurality of contact fingers 772, a plurality of conduction terminals 776, and a terminal module base 774. In one embodiment of the present invention, the contact fingers (or connection device) 772 and conduction terminals 776 are formed from conducting metals such as copper, but it is anticipated that in other embodiments, other conducting metals may be used. The number, position, and shape of the contact fingers 772 conform to the number, position, and shape of the connector openings 751, of the top cover (shown in FIG. 8) such that each contact finger 772 protrudes through one connector openings 751, as will be discussed further hereinbelow.

The terminal module base 774 is shown to be generally flat and rectangular shaped. In one embodiment of the present invention, the terminal module base 774 holds the conduction terminals 776 and contact fingers 772 in place, and connects each conduction terminal 776 to one contact finger 772. In other embodiments, the connection between the contact fingers 772 and the conduction terminals 776 are not one-to-one. The purpose and function of the terminal module base 774 is discussed further hereinbelow.

In the embodiment of the present invention shown in FIG. 7(a), the smaller format memory card 760 is a standard Micro-MMC card, commonly available through commercial channels. In other embodiments of the present invention, it is anticipated that other memory cards with dimensions smaller than the electronic data flash memory card 700 may also be used. The smaller format memory card 760 is shown to include a plurality of small format contact plates 762 along one edge thereof, and a side notch 764, shaped generally as a rectangular cutout, along a portion of another edge.

In one embodiment of the present invention, the number of small format contact plates 762 on the smaller format memory card 760, the number of conduction terminals 776 on the terminal module 770, and the number of contact fingers 772 on the terminal module 770 are the same, and when the conduction terminals 776 on the terminal module 770 connect with the small format contact plates 762 on the smaller format memory card 760, as will be further discussed hereinbelow, the terminal module base 774 merely makes one-to-one connection between the small format contact plates 762 on the smaller format memory card 760 and the contact fingers 772 on the terminal module 770.

In other embodiments of the present invention, the number of small format contact plates 762 on the smaller format memory card 760 do not match the number of contact fingers 772 on the terminal module 770, in which case the terminal module base 774 may include logic and circuitry to conform the standard used by the smaller format memory card 760 to the standard that the contact fingers 772 comply with. The logic and circuitry used to convert one memory card standard to another is known to those familiar with the art, and those familiar with the art can easily form the necessary circuitry and logic.

The bottom cover 780 is shown to be generally square in shape, having a corner notch 778, shaped generally as a triangular cutout, along one corner thereof, thus matching generally the shape of the top cover 750. The bottom cover 780 is shown to further include two raised platforms 785, shaped generally as an elevated area on one surface along portions of the edge thereof, and a raised edge 783 extending along portions of two edges and the full length of a third edge thereof. The raised platforms 785 and raised edge 783 jointly surround a central cavity 786. The central cavity 786 is shown to extend into the raised platform 785 in two places, forming two compression channels 781 which are shown to be shaped as linear cutouts along the raised platforms 785. The bottom cover 780 is shown to further include a plurality of connection finger chambers 784 along the edge opposite to the edge on which the opening 787 is situated. The connection finger chambers 784 are shown to be generally square-shaped cavities formed by a plurality of separators 784(a).

The bottom cover 780 is shown to further include an opening 787 substantially in the middle of and along the edge opposite to the edge on which the connection finger chambers 784 are situated. The opening 787 is generally an opening formed by the separation between the two raised platform 785, and a rectangular cutout of a portion of the central cavity 786. The length of the opening 787 is substantially equal to the length of the opening 757 on the top cover 750 (shown in FIG. 7).

In assembly, the terminal module 770 is pre-embedded into the end of the top cover 750 where the connector openings 751 are located, such that each contact finger 772 protrudes through one connector opening 751, and the conduction terminals 776 rest inside the central cavity 756. Thereafter, the top cover 750 and the bottom cover 780 are ultrasonically bonded together, using the ultrasonic bonders 754 along the peripheral edges of the top cover 750, thus forming a rigid casing. The connection finger chambers 784 hold the terminal module 770 firmly in place. Thereafter, the smaller format memory card 860 is inserted into the casing formed by the ultrasonically bonded top cover 850 and bottom cover 880, as will be discussed further hereinbelow.

Referring now to FIG. 7(b), an angular front top view 701 and an angular bottom rear view 702 of the electronic data flash memory card 700 is shown according to an embodiment of the present invention. In FIG. 7(b), the electronic data flash memory card 700 is shown assembled.

The electronic data flash memory card 700 is shown to be generally square shaped, having a corner notch 795, shaped generally as a triangular cutout on one corner. The electronic data flash memory card 700 is shown to further include a plurality of contact points 791, which are formed when the contact fingers 772 (shown in FIG. 7(a)) protrude through the connector openings 751 of the top cover 750 (shown in FIG. 7). In one embodiment of the present invention, the electronic data flash memory card 700 conforms, in shape and dimensions, to the shape and dimension of an SD or MMC card, and the shape, number, and position of the contact points 791 conform to the shape, number, and position of pins on an SD or MMC card. In other embodiments, it is anticipated that the electronic data flash memory card 700 and the contact points 791 may conform to standards for other memory cards used in the industry.

The electronic data flash memory card 700 is further shown to include a plurality of breakaway tabs 798 and a breakaway notch 799. The breakaway tabs 798 are formed when the breakaway tabs 738 on the top cover 750 (shown in FIG. 7) are joined with the breakaway tabs 788 on the bottom cover 780 (shown in FIG. 7(a)). The breakaway notch 799 is formed when the breakaway notch 739 on the top cover 750 (shown in FIG. 7) is joined with the breakaway notch 789 on the bottom cover 780 (shown in FIG. 7(a)). The function and purpose of the breakaway tabs 798 are similar to the function and purpose of the breakaway tabs 38(c) (shown in FIGS. 2, 3(a), 3(b), and 4), and further discussion thereof is avoided in order to eliminate redundancy. Furthermore, the function and purpose of the breakaway notch 799 is similar to the function of the breakaway notch 39 (shown in FIG. 2) and further discussion thereof is avoided in order to eliminate redundancy.

In the bottom rear view 702, the electronic data flash memory card 700 is shown to include an insertion slot 794 which is shown to be a generally rectangular opening formed by the joining of the opening 757 of the top cover 750 (shown in FIG. 7) with the opening 787 of the bottom cover 780 (shown in FIG. 7 (a)).

A portion of the back of the smaller format memory card 760 is shown protruding through the insertion slot 794. The smaller format memory card 760 is shown to include a pull slot 763, which is generally shaped as a linear channel situated along the back edge thereof.

In operation, the electronic data flash memory card 700 is assembled when a smaller format memory card 760 (shown in FIG. 7(a)) is inserted, with its small format contact plates 762 pointing in, into the insertion slot 794. The protrusions posts 752 (shown in FIG. 7) and 782 (shown in FIG. 7(a)) fit around the smaller format memory card 760 and the side notch 764 thereof, holding the smaller format memory card 760 in place. The small format contact plates 762 make contact with the conduction terminals 776 (shown in FIG. 7(a)).

Furthermore, the smaller format memory card 760 may advantageously be removed from the electronic data flash memory card 700 by placing a fingernail or other similarly sharp object into the pull slot 763, then pulling the smaller format memory card 760 out through the insertion slot 794. The compression channels 781 and 748 compress, causing the central cavities 786 and 756 to expand, allowing the smaller format memory card 760 to snap out. The electronic data flash memory card 700 advantageously allows a user to have a smaller format memory card 760 connected into a host device directly, or to a different host device, with different connectors, by inserting the smaller format memory card 760 into the insertion slot 794, and using the connector 791 to connect the electronic data flash memory card 700 to the different format host device. Furthermore, the electronic data flash memory card 700 advantageously allows a user to use more than one smaller format memory card 760 with a single electronic data flash memory card 700.

Referring now to FIG. 8, a top angular view of a top cover 850, which is a component of an electronic data flash memory card is shown according to yet another embodiment of the present invention.

The top cover 850 is shown to be generally square in shape, with two raised platforms 855 situated generally on one surface and adjacent to two opposite edges thereof, a central cavity 856 generally in the middle thereof, and a corner notch 858, shown to be generally shaped as a triangular cutout, on one corner thereof and adjacent to one of the edges adjacent to one of the raised platforms 855. In one embodiment of the present invention, the corner notch 858 is shaped generally to conform to the SD or MMC size standards, but it is anticipated that in other embodiments, the corner notch 858 may be shaped to conform to standards of other memory cards. Shown situated inside the left raised platform 755 is a compression channel 848, shaped generally as a linear cutout in the left raised platform 855.

The top cover 850 is shown to further include raised edges 853 extending along the edge adjacent to the corner notch 858, and extending around to merge with the raised platforms 855. The top cover 850 is shown to further include a plurality of ultrasonic bonders 854, shown to be formed as raised protrusions, narrower in width than the raised edges 853, along three edges, and a portion of a fourth edge. Along the inner edge of the raised platform 855 and facing the central cavity 856 are shown formed a plurality of protrusion posts 852, which is shown to be formed generally as solid, semi-cylindrical protrusions.

The top cover 850 is shown to further include an opening 857 situated substantially in the middle of the edge opposite to the edge on which the corner notch 858 is situated and between the two edges adjacent to the raised platforms 855. The opening 857 is shown to be a gap formed by the separation between the two raised platforms 853. The length of the opening 857 is substantially equal to the width of a smaller format memory card 860, as will be discussed further hereinbelow.

The top cover 850 is shown to further include a plurality of connector openings 851, shown to be formed generally as rectangular cutouts, along one edge thereof. In an embodiment of the present invention, the shape, number, and position of the connector openings 851 conform to the shape, number, and position of connectors in the SD or MMC standards, but in other embodiments, it is anticipated that the shape, number, and position of the connector openings 851 conform to other standards used and adopted by the industry.

The top cover 850 is shown to further include a plurality of breakaway tabs 838 situated along an edge adjacent to one of the raised platforms 855, and a breakaway notch 839 along the opposite edge. It should be noted that the number of breakaway tabs 838 and breakaway notch 839 shown is exemplary, and it is anticipated that in other embodiments, different numbers of breakaway tabs 838 or breakaway notches 839 may be used. The shape and function of the breakaway tabs 838 and the breakaway notch 839 are similar to the breakaway tabs 38 and breakaway notches 39, discussed hereinabove, and further discussion thereof is avoided to eliminate redundancy.

Referring now to FIG. 8(a) an exploded view 801, an angular front top view 802 and an angular rear bottom view 803 of an electronic data flash memory card 800 is shown according to an embodiment of the present invention.

In the exploded view 801, the electronic data flash memory card 800 is shown to include a top cover 850, a smaller format memory card 860, a terminal module 870, and a bottom cover 880. The structure and components of the top cover 850 were discussed hereinabove, and additional discussion thereof is avoided in order to eliminate redundancy.

The terminal module 870 is shown to include a plurality of contact fingers 872, a plurality of conduction terminals 876, and a terminal module base 874. In one embodiment of the present invention, the contact fingers 872 and conduction terminals 876 are formed from conducting metals such as copper, but it is anticipated that in other embodiments, other conducting metals may be used. The number, position, and shape of the contact fingers 872 conform to the number, position, and shape of the connector openings 851 of the top cover (shown in FIG. 8) such that each contact finger 872 protrudes through one connector opening 851, as will be discussed further hereinbelow.

The terminal module base 874 is shown to be generally flat and rectangular shaped. In one embodiment of the present invention, the terminal module base 874 holds the conduction terminals 876 and contact fingers 872 in place, and connects each conduction terminal 876 to one contact finger 872. In other embodiments, the connection between the contact fingers 872 and the conduction terminals 876 are not one-to-one. The purpose and function of the terminal module base 874 will be discussed further hereinbelow.

In the embodiment of the present invention shown in FIG. 8(a), the smaller format memory card 860 is a standard Micro-SD card, commonly available through commercial channels. In other embodiments of the present invention, it is anticipated that other memory cards with dimensions smaller than the electronic data flash memory card 800 may also be used. The smaller format memory card 860 is shown to include a plurality of small format contact plates 862 alone one edge thereof, and two side notches 864, shaped generally as a rectangular cutouts, along a portion of another edge.

In one embodiment of the present invention, the number of small format contact plates 862 on the smaller format memory card 860, the number of conduction terminals 876 on the terminal module 870, and the number of contact fingers 872 on the terminal module 870 are the same, and when the conduction terminals 876 on the terminal module 870 connect with the small format contact plates 862 on the smaller format memory card 860, as will be further discussed hereinbelow, the terminal module base 874 merely makes one-to-one connection between the small format contact plates 862 on the smaller format memory card 860 and the contact fingers 872 on the terminal module 870.

In other embodiments of the present invention, the number of small format contact plates 862 on the smaller format memory card 860 do not match the number of contact fingers 872 on the terminal module 870, in which case the terminal module base 874 may include logic and circuitry to conform the standard used by the smaller format memory card 860 to the standard that the contact fingers 872 comply with. The logic and circuitry used to convert one memory card standard to another is available in the industry, and those familiar with the art can easily form the necessary circuitry and logic.

The bottom cover 880 is shown to be generally square in shape, having a corner notch 878, shaped generally as a triangular cutout, along one corner thereof, thus matching generally the shape of the top cover 850. The bottom cover 880 is shown to further include two raised platform 885, shaped generally as an elevated area on one surface, along portions of the edge thereof, and a raised edge 883 extending along portions of two edges and the full length of a third edge thereof. The raised platforms 885 and raised edge 883 jointly surround a central cavity 886. The central cavity 886 is shown to extend into the raised platform 885, forming a compression channel 881 which is shown to be shaped as linear cutouts with a semi-circular end along the raised platform 885. The bottom cover 880 is shown to further include a plurality of connection finger chambers 884 along one edge thereof. The connection finger chambers 884 are shown to be generally square-shaped cavities formed by a plurality of separators 884(a).

The bottom cover 880 is shown to further include an opening 887 along the edge opposite to the edge on which the connection finger chambers 884 are situated. The opening 887 is generally an opening formed by the separation between the two raised platform 885, and a rectangular cutout of a portion of the central cavity 886. The length of the opening 887 is substantially equal to the length of the opening 857 on the top cover 850 (shown in FIG. 7).

In assembly, the terminal module 870 is pre-embedded into the end of the top cover 850 where the connector openings 851 are located, such that each contact finger 872 protrudes through one connector opening 851, and the conduction terminals 876 rest inside the central cavity 856. Thereafter, the top cover 850 and the bottom cover 880 are ultrasonically bonded together, using the ultrasonic bonders 854 along the peripheral edges of the top cover 850, thus forming a rigid casing. The connection finger chambers 884 hold the terminal module 870 firmly in place. Thereafter, the smaller format memory card 760 is inserted into the casing formed by the ultrasonically bonded top cover 750 and bottom cover 780, as will be discussed further hereinbelow.

In the angular front top view 802 and the angular rear bottom view 803, the electronic data flash memory card 800 is shown to be generally square shaped, having a corner notch 895, shaped generally as a triangular cutout on one corner. The electronic data flash memory card 800 is shown to further include a plurality of contact points 891, which are formed when the contact fingers 872 protrude through the connector openings 851 of the top cover 850 (shown in FIG. 8). In one embodiment of the present invention, the electronic data flash memory card 800 conforms, in shape and dimensions, to the shape and dimension of an SD or MMC card, and the shape, number, and position of the contact points 891 conform to the shape, number, and position of pins on an SD or MMC card. In other embodiments, it is anticipated that the electronic data flash memory card 800 and the contact points 891 may conform to other memory cards used in the industry.

The electronic data flash memory card 800 is further shown to include a plurality of breakaway tabs 898 and a breakaway notch 899. The breakaway tabs 898 are formed when the breakaway tabs 838 on the top cover 850 (shown in FIG. 8) are joined with the breakaway tabs 888 on the bottom cover 880. The breakaway notch 899 is formed when the breakaway notch 839 on the top cover 850 (shown in FIG. 8) is joined with the breakaway notch 889 on the bottom cover 880. The function and purpose of the breakaway tabs 898 are similar to the function of the breakaway tabs 38 (shown in FIGS. 2, 3(a), 3(b), and 4 above), and further discussion thereof is avoided in order to eliminate redundancy. Furthermore, the function and purpose of the breakaway notch 899 is similar to the function of the breakaway notch 39 (shown in FIG. 2) and further discussion thereof is avoided in order to eliminate redundancy.

In the bottom rear view 803, the electronic data flash memory card 800 is shown to include an insertion slot 894 which is shown to be a generally rectangular opening formed by the joining of the opening 857 of the top cover 850 (shown in FIG. 8) with the opening 887 of the bottom cover 880.

A portion of the back of the smaller format memory card 860 is shown protruding through the insertion slot 894. The smaller format memory card 860 is shown to include a pull slot 863, which is generally shaped as a linear channel situated along the back edge thereof.

In operation, the electronic data flash memory card 800 is assembled when a smaller format memory card 860 is inserted, with its small format contact plates 862 pointing in, into the insertion slot 894. The protrusions post 852 (shown in FIG. 8) and 882 fit around the smaller format memory card 860 and the side notches 864, holding the smaller format memory card 860 in place. The small format contact plates 862 make contact with the conduction terminals 876. The fully assembled electronic data flash memory card 800 is a complete memory card.

Furthermore, the smaller format memory card 860 may advantageously be removed from the electronic data flash memory card 800 by placing a fingernail or other similarly sharp object into the pull slot 863, then pulling the smaller format memory card 860 out through the insertion slot 894. The compression channels 881 and 848 compress, causing the central cavities 886 and 856 to expand, allowing the smaller format memory card 860 to snap out. The electronic data flash memory card 800 advantageously allows a user to have a smaller format memory card 860 connected into a host device directly, or to a different host device, with different connectors, by inserting the smaller format memory card 860 into the insertion slot 894, and using the connector 891 to connect the electronic data flash memory card 800 to a different format host device. Furthermore, the electronic data flash memory card 800 advantageously allows a user to use more than one smaller format memory card 860 with a single electronic data flash memory card 800.

What is claimed is:

1. An electronic data flash memory card comprising:
a top cover including a plurality of ultrasonic bonders, a connection device, and a plurality of top cover breakaway tabs;
a printed circuit board assembly (PCBA) including at least one memory integrated circuit (IC) and at least one controller IC, and
a bottom cover including a plurality of bottom cover breakaway tabs
said top cover and bottom cover being ultrasonically bonded together to at least partially encase said PCBA, said top cover breakaway tabs and bottom cover breakaway tabs aligned to form memory card tabs,
said controller IC operative to cause said electronic data flash memory card to communicate with an external host device through the connection device for the purpose of retrieving data files from said external host device and storing said data files on said memory IC and retrieving data files from said memory IC and transferring said data files to said external host device,
said breakaway tabs being removable by exertion of pressure thereon, the removal of said breakaway tabs causing locking or unlocking said electronic data flash memory card.

2. The electronic data flash memory card as recited in claim 1, wherein
the bottom and top covers further include a plurality of breakaway notches;
said breakaway notches being removable by the user by exertion of pressure thereon,
the removal of said breakaway notches by the user causing the electronic data flash memory card, when connected to an external host device, to be firmly held in place by a protrusion in the external host device.

3. The electronic data flash memory card as recited in claim 1, wherein
the top cover includes a plurality of positioning posts;
the bottom cover includes a plurality of holes,
with said positioning posts from the top cover inserted into said holes in the bottom cover when the top cover is bonded to the bottom cover.

4. The electronic data flash memory card as recited in claim 1, wherein
said connection device comprises a plurality of contact fingers situated on the top cover,
said contact fingers being used to connect said electronic data flash memory card with said external host device.

5. The electronic data flash memory card as recited in claim 4, wherein
the number, position, and shape of said contact fingers match the number, position, and shape of contact fingers in the MMC format;
the shape of said electronic data memory card conforms to the shape of a memory card in the MMC format, and
said electronic data flash memory card communicates with the external host device in a manner conforming to the MMC standard.

6. The electronic data flash memory card as recited in claim 4, wherein
the number, position, and shape of said contact fingers match the number, position, and shape of contact fingers in the SD format;
the shape of said electronic data memory card conforms to the shape of a memory card in the SD format, and
said electronic data flash memory card communicates with the external host device in a manner conforming to the SD standard.

7. The electronic data flash memory card as recited in claim 1, wherein at least one memory IC is of multi-level cell (MLC) structure.

8. The method of manufacturing an electronic data flash memory card comprising
forming a top cover including a plurality of contact fingers and a plurality of breakaway tabs and breakaway notches;
forming a printed circuit board assembly (PCBA) including at least one memory integrated circuit (IC) and one controller IC;
forming a bottom cover including a plurality of breakaway tabs and breakaway notches;
placing said PCBA between said top cover and bottom cover, and
ultrasonically bonding said top cover to said bottom cover.

9. An electronic data flash memory card comprising:
a printed circuit board (PCB) itself comprising an external connection device and a plurality of metal pads, and
at least one small format memory card electrically connected to said metal pads on said PCB, wherein
said electronic data memory card communicates with an external host device through said connection device for the purpose of retrieving data files from said external host device and storing said data files on said small format memory card and retrieving data files from said small format memory card and transferring said data files to said external host device.

10. The electronic data flash memory card recited in claim 9 wherein said connection device comprises a plurality of contact fingers.

11. The electronic data flash memory card recited in claim 11 wherein said contact fingers and said small format memory card are situated on opposite sides of the printed circuit board.

12. The electronic data flash memory card recited in claim 9 wherein said small format memory card is connected to said printed circuit board using surface mount technology.

13. The electronic data flash memory card recited in claim 10, wherein
the number, position, and shape of said contact fingers match the number, position, and shape of contact fingers in the MMC format;
the shape of said electronic data memory card conform to the shape of a memory card in the MMC format, and
said electronic data flash memory card communicates with the external host device in a manner conforming to the MMC standard.

14. The electronic data flash memory card recited in claim 10, wherein
the number, position, and shape of said contact fingers match the number, position, and shape of contact fingers in the SD format;
the shape of said electronic data memory card conform to the shape of a memory card in the SD format, and
said electronic data flash memory card communicates with the external host device in a manner conforming to the SD standard.

15. The electronic data flash memory card recited in claim 9, wherein
the small format memory card conforms to the mini-MMC format.

16. The electronic data flash memory card recited in claim 9, wherein
the small format memory card conforms to the micro-MMC format

17. The electronic data flash memory card as recited in claim 9, wherein
said PCB further includes a plurality of breakaway tabs;
said breakaway tabs being connected to the said PCB in a manner allowing said breakaway tabs to be broken off and removed by a user upon exertion of pressure,
the removal of said breakaway tabs by the user locking or unlocking said electronic data flash memory card.

18. An electronic data flash memory card comprising:
a chip on board (COB);
said COB comprising at least memory circuitry, controller circuitry, and a connection device;
said controller circuitry enabling said electronic data flash memory card to communicate with an external host device through the connection device for the purpose of retrieving data files from said external host device and storing said data files on said memory circuitry and retrieving data files from said memory circuitry and transferring said data files to said external host device.

19. The electronic data flash memory card as recited in claim 18, wherein
said connection device comprises a plurality of contact fingers situated on the electronic data flash memory card,
said contact fingers being used to connect said electronic data flash memory card with said external host device.

20. The electronic data flash memory card as recited in claim 18, wherein
the number, position, and shape of said contact fingers match the number, position, and shape of contact fingers in the MMC format;
the shape of said electronic data memory card conforms to the shape of a memory card in the MMC format, and
said electronic data flash memory card communicates with the external host device in a manner conforming to the MMC standard.

21. The electronic data flash memory card as recited in claim 18, wherein
the number, position, and shape of said contact fingers match the number, position, and shape of contact fingers in the SD format;
the shape of said electronic data memory card conforms to the shape of a memory card in the SD format, and
said electronic data flash memory card communicates with the external host device in a manner conforming to the SD standard

22. The electronic data flash memory card as recited in claim 18, wherein
the memory circuitry is of the MLC architecture.

23. A method for manufacturing electronic data flash memory cards comprising:
fabrication of memory and controller circuitry in the form of one or more integrated circuits (ICs);
placing said memory and controller circuitry in a mold;
attaching electrical connectors to said memory and controller circuitry, and
pouring resin, epoxy, or plastic material on said circuitry,
yielding an electronic data flash memory card in COB format, wherein
said controller circuitry enables said electronic data flash memory card to communicate with an external host device through the connectors for the purpose of retrieving data files from said external host device and storing said data files on said memory circuitry and retrieving data files from said memory circuitry and transferring said data files to said external host device.

24. An electronic data flash memory card comprising:
An top cover including a plurality of ultrasonic bonders, an opening, a central cavity, and a plurality of connector openings;
a terminal module including a plurality of contact fingers, and a plurality of conduction terminals;
a smaller format memory card including a plurality of small format contact plates, and
a bottom cover including a central cavity and an opening,
said terminal module being embedded into said top cover such that said contact fingers in said terminal module protrude through said connector openings in said top cover forming a plurality of contact points,
said top cover and bottom cover being ultrasonically bonded together using said ultrasonic bonders,
whereupon said opening in the top cover and said opening in the bottom cover jointly form an insertion slot,
said smaller format memory card being capable of being removably inserted, through said insertion slot, whereupon the small format contact plates on said smaller format memory card make contact with the conduction terminals in said terminal module,
the contact points being capable of communicating with an external host for the purpose of retrieving data files from said external host device and storing said data files on said smaller format memory card and transferring data files from said smaller format memory card to said external host.

25. The electronic data flash memory card as recited in claim 24, wherein
said smaller format memory card is a Micro-MMC card.

26. The electronic data flash memory card as recited in claim 24, wherein
said smaller format memory card is a Micro-SD card.

27. The electronic data flash memory card as recited in claim 24, wherein
the shape, number, and position of said contact points conforms to the shape, number, and position of contact points in an MMC card;
the dimensions of said electronic data flash memory card conform to the dimensions of an MMC card, and
said electronic data flash memory card communicates with said host device through the MMC communication standard.

28. The electronic data flash memory card as recited in claim 24, wherein
the shape, number, and position of said contact points conforms to the shape, number, and position of contact points in an SD card;
the dimensions of said electronic data flash memory card conform to the dimensions of an SD card, and
said electronic data flash memory card communicates with said host device through the SD communication standard.

29. The electronic data flash memory card as recited in claim 24 wherein
the top cover and bottom cover further include a plurality of breakaway tabs;
said breakaway tabs being removable by the user by exertion of pressure thereon,
the removal of said breakaway tabs by the user locking or unlocking said electronic data flash memory card.

30. The electronic data flash memory card as recited in claim 24 wherein
the bottom cover and top cover further include a plurality of breakaway notches;
said breakaway notches being removable by the user by exertion of pressure thereon;
the removal of said breakaway notches by the user causing the electronic data flash memory card, when connected to an external host device, to be firmly held in place by a protrusion in the external host device.
